(19) United States
(12) Patent Application Publication
(10) Pub. No.: US 2008/0237680 A1
(43) Pub. Date: Oct. 2, 2008

(54) Enabling flash cell scaling by shaping of the floating gate using spacers

(76) Inventors: Kiran Pangal, Fremont, CA (US); Krishna Parat, Palo Alto, CA (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/728,829

(22) Filed: Mar. 27, 2007

(51) Int. Cl. H01L 29/788; H01L 21/336

(52) U.S. Cl. 257/315; 438/263; 438/294; 257/E29.3; 257/E21.409

(57) ABSTRACT

According to embodiments of the invention, an inverted “T” shaped gate can be formed for transistor flash memory cells to reduce feature sizes, to reduce pitch size, to increase gate coupling ratio and/or to reduce parasitic capacitive effects between adjacent flash cells or cell floating gates, such as with optimization of control gate distance between field gates. Such feature sizes include channel width; isolation region width; width of a portion of a gate electrode and/or half-pitch distance between adjacent cells or rows of transistors (e.g., cells).

### FIELD

Circuit devices and the manufacture and structure of circuit devices.

### BACKGROUND

Reducing size of circuit devices (e.g., integrated circuits (IC), transistors, flash memory, resistors, capacitors, etc.) on a semiconductor (e.g., silicon) substrate is typically a major factor considered during design, manufacture, and operation of those devices. In some cases, “scaling” may be used to “scale” down the size or scale of the devices or space from a feature of one device to the similar feature of an adjacent device. For example, during design and manufacture or forming of flash memory devices and other similar electronic devices, it is often desirable to reduce size or scale of (or between) devices, cells, transistors, bit lines (BL), and/or word lines (WL) of those devices.

Such flash memory devices or cells may include n-channel polysilicon gate oxide transistor devices with floating polysilicon gates (and/or non-volatile memory devices. For example, non-volatile memory, and/or flash memory transistors (e.g., cells) may be described as having data ‘programmed’ or stored therein until it is reset or ‘erased’. After being reset or erased, data may be again stored or ‘programmed’ into the non volatile memory until it is again erased. It can be appreciated that this process may be performed repeatedly.

### BRIEF DESCRIPTION OF THE DRAWINGS

The features, aspects, and advantages of embodiments of the invention will become more thoroughly apparent from the following detailed description, appended claims, and accompanying drawings in which:

FIG. 1A is a schematic cross sectional view of a portion of a substrate having a gate electrode formed over a channel region in an active region of a transistor.

FIG. 1B is a schematic top view of a portion of a substrate showing an array of flash cells arranged along bit lines and word lines.

FIG. 1C is a schematic cross sectional view of FIG. 1B through perspective A showing a portion of a substrate having a gate electrode formed over a channel region in an active region of a transistor.

FIG. 1D is a schematic cross sectional view of FIG. 1B through perspective B showing of a portion of a substrate having a gate electrode formed over a channel region in an active region of a transistor.

FIG. 2 is a schematic cross sectional view of a portion of a substrate having a dielectric layer on a first portion of the gate electrode over a channel region to define an active region, and isolation regions between the active regions.

FIG. 3 is a schematic cross sectional view of FIG. 2 after removal of a thickness of the isolation regions, and removal of the dielectric layer from on the first portion of the gate electrode.

FIG. 4 is a schematic cross sectional view of FIG. 3 after forming a conformal layer of dielectric material on a top surface of the first portion of the gate electrode and on sidewalls of isolation regions adjacent the top surface.

FIG. 5 is a schematic cross sectional view of FIG. 4 after removing the conformal layer of dielectric material from the top surface of the first portion of the gate electrode.

FIG. 6 is a schematic cross sectional view of FIG. 5 after forming a second portion of the gate electrode on the top surface of the first portion of the gate electrode.

FIG. 7 is a schematic cross sectional view of FIG. 6 after removing a thickness of the second portion of the gate electrode.

FIG. 8 is a schematic cross sectional view of FIG. 7 after removing an additional thickness of the second portion of the gate electrode and a thickness of the isolation regions.

FIG. 9 is a schematic cross sectional view of FIG. 8 after removing a thickness of the isolation regions and removing the spacers of the conformal dielectric layer to expose the sidewalls of the first and second portions of the gate electrode.

FIG. 10 is a schematic cross sectional view of FIG. 9 after forming a conformal dielectric layer over the expose the sidewalls of the first and second portions of the gate electrode.

### DETAILED DESCRIPTION

Reducing pitch, distance, or scale of or between adjacent transistors such as flash memory cells may decrease size, and/or decrease power requirements for those transistors. For instance, the pitch between flash memory cells may describe a cross-sectional perspective distance along the word line between similar locations (e.g., a surface, end, corner, sidewall) of features (e.g., a diffusion region, channel, gate electrode, tunnel dielectric, or insulator) of lines or rows of adjacent cells. Thus, the half-pitch between flash cells may be perpendicular to, and/or independent of the length of the channel between diffusion regions (e.g., may be independent of the distance between the source and the drain under the gate). Such ‘scaling’ may take into account, maintain, and/or increase certain factors, such as the ability to accommodate sufficient inter-layer dielectric (ILD) and word line (WL) (e.g., control gate) material (e.g., width or thickness) between adjacent cells; having a sufficient cell active width; having good capacitive coupling between the control gate and the floating gate for device transistor performance (e.g., device programming, erasing, and reading); and/or other similar factors. Thus, an array of flash memory cells may be designed to: (1) increase or maintain the above factors, (2) reduce pitch or space between cell, and also (3) maintain performance and reliability.

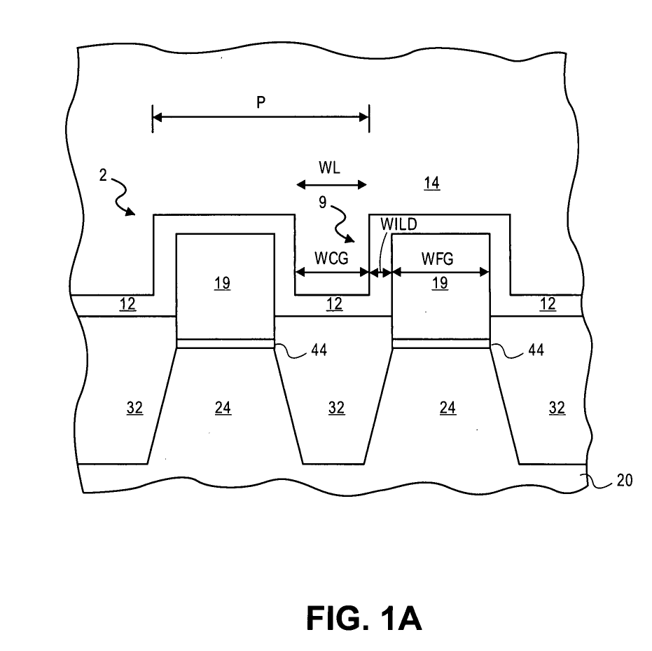

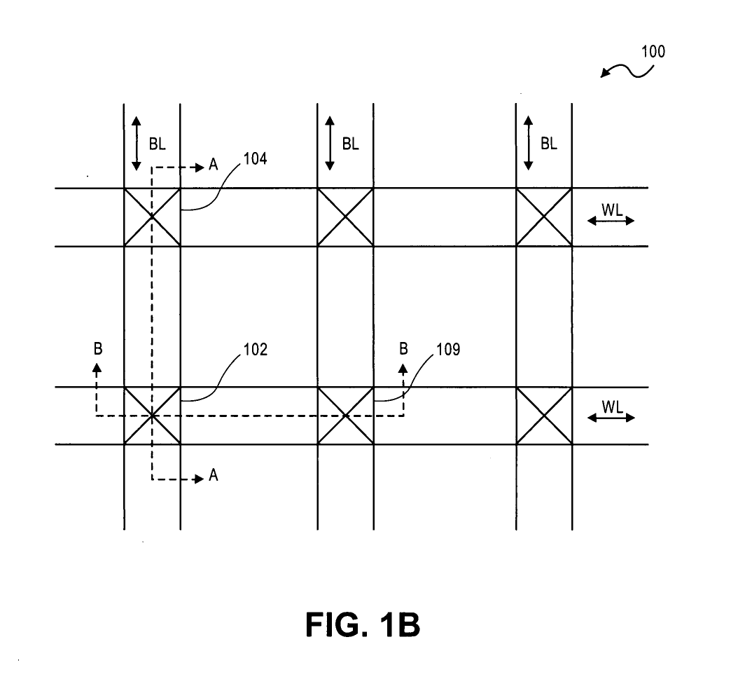

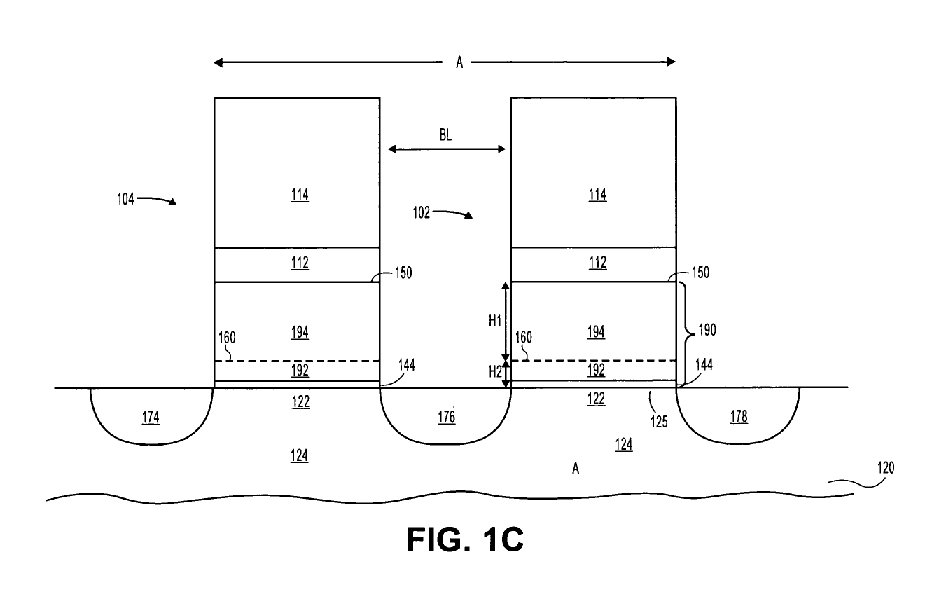

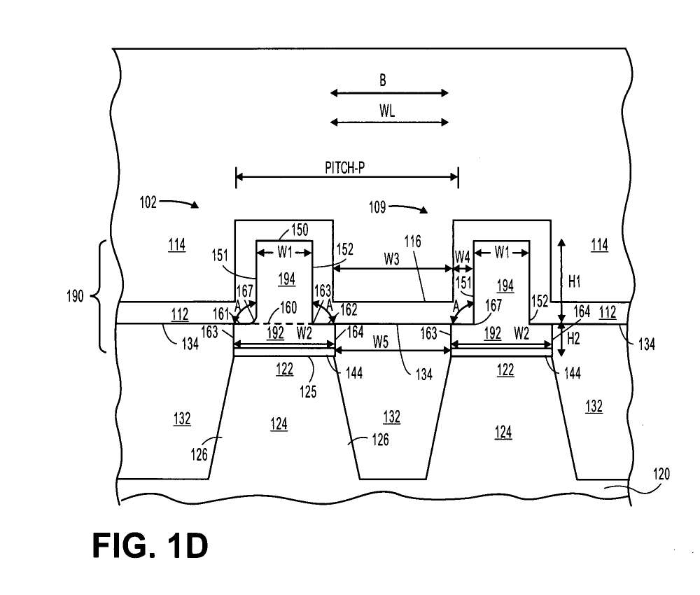

FIG. 1A is a schematic cross sectional view of a portion of a substrate having a gate electrode formed over a channel region in an active region of a transistor. FIG. 1A shows a cross sectional view of transistor 2 and transistor 9 formed on substrate 20, such as a cross sectional view along word line WL or along control gate layer 14 (e.g., the word line may be the control gate layer). The transistors have gate electrode 19 over well or active region 24 and tunnel dielectric 44 on active region 24 and below electrode 19. Isolation regions 32 are shown formed adjacent to, touching, beside or between active regions 24. Isolation regions 32 may be described as trench isolation or shallow trench isolation (STI). FIG. 1A also shows conformal dielectric layer 12 formed on electrode 19 and regions 32. Layer 12 may be an inter-poly dielectric. Conductive material layer 14 is formed on layer 12. Layer 14 may be a control gate or word line. Additional transistors similar to transistors 2 and 9 may exist to the left and right of those transistors, such as to form a line of transistors having a cross-section similar to that shown for those transistors.

Pitch P is shown as the pitch between transistors 2 and 9. Thus, a half-pitch may be defined as half of the distance of pitch P, such as a distance from the mid point of the gate of transistor 2 to the midpoint of the space between transistors 2 and 9. Scaling beyond or below 50 nanometers (nm) half-pitch (e.g., between lines or rows of adjacent cells) along the word line may not be possible with current electrode technology. Specifically, the space between floating gates (FG) of adjacent cells becomes too narrow to be able to accommodate the ILD that is typically 15 nm thick or wide (e.g., see WILD) and the control gate (CG) polywrap-around that needs to be at least 20 nm wide (e.g., see WCG). In this case, the combined thickness or dimension of the ILD and CG material may be at least 50 nm, which would be greater than the half-pitch size of or between cells of the transistors. Thus, this design cannot be practically or successfully fabricated into reliably functioning devices.

According to embodiments of the invention, an inverted “T” shaped gate can be formed for transistor flash cells to reduce feature sizes, to reduce pitch size, to increase gate coupling ratio and/or to reduce parasitic capacitive effects between adjacent flash cells or cell floating gates, such as with optimization of control gate distance between field gates. Such feature sizes include channel width; isolation region width; width of a portion of a gate electrode and/or half-pitch distance between adjacent cells or rows of transistors (e.g., cells).

Flash memory may be organized into a grid or array formation of flash transistors or “cells”. FIG. 1B is a schematic top view of a portion of a substrate showing an array of flash cells arranged along bit lines and word lines. FIG. 1B shows array 100 of cells, each located at the intersection of a bit line (BL) and a word line (WL), such as indicated by the box having an “X” at each intersection. Array 100 includes transistors (e.g., cells) 102 and 104 along perspective A and transistors (e.g., cells) 102 and 109 along perspective B.

Programming of the cells can be done by applying a proper electric field or “bias” across a tunnel dielectric (e.g., dielectric 44), which causes electrons to be stored in a floating gate (e.g., electrode 19). Similarly, the cells can be erased by applying a proper electric field or “bias” (e.g., a field that has an opposite polarity as compared to the field for programming) across the tunnel dielectric (e.g., dielectric 44), which causes electrons stored in a floating gate to be removed (such as by causing them to tunnel through dielectric 44 and into active region 24). The electric field may be applied using bit lines (BL) in one direction and word lines (WL) in another direction across lines or rows of cells, or devices. Once programmed, the floating gate may retain the charged data (e.g., a “bit” of data) for a long period of time (e.g., five years) or until it is erased.

FIG. 1C is a schematic cross sectional view of FIG. 1B through perspective A showing a portion of a substrate having a gate electrode formed over a channel region in an active region of a transistor. FIG. 1C shows a cross sectional view of transistor 102 and transistor 104 along the bit line (BL) of a flash cell array (e.g., along the direction of bit line (BL)). The transistors have gate electrode 190 with first portion 192 over well or active region 124 and second portion 194 on surface 160 of first portion 192. For instance, portion 194 may be described as on, over, above or touching surface 160 and/or portion 192. Second portion 194 is shown having height H1 which is greater than height H2 of first portion 192.

FIG. 1C shows tunnel dielectric 144 on surface 125 of active region 124 and below portion 192. Also, diffusion regions 174, 176 and 178 are shown adjacent to and between regions 124 of adjacent transistors along the BL. FIG. 1C also shows conformal dielectric layer 112 formed on electrode 190. Layer 112 may be an inter-poly dielectric. Conductive material layer 114 is formed on layer 112. Layer 114 may be a control gate or word line. Additional transistors similar to transistors 102 and 104 may exist to the left and right of those transistors, such as to form a line of transistors having a cross-section similar to that shown for those transistors.

FIG. 1D is a schematic cross sectional view of FIG. 1B through perspective B showing of a portion of a substrate having a gate electrode formed over a channel region in an active region of a transistor. FIG. 1D shows a cross sectional view of transistor 102 and transistor 109 such as a cross sectional view perpendicular to the cross section shown in FIG. 1C. Thus, FIG. 1D may show a cross sectional view of transistor 102 and transistor 109 along the word line (WL) of a flash cell array (e.g., along the direction of extension of CG layer 114). Thus, pitch P is shown as the pitch between transistor 102 and 109, such as a distance between similar features or surfaces (e.g., sidewalls 163 or 164 of transistors 102 and 109) of the transistors. Thus, a half-pitch would be defined as half of the distance of pitch P.

According to embodiments, first portion 192 is formed on surface 125 of channel 122 of active region 124. Similarly, in some embodiments, first portion 192 may include or be formed on tunnel dielectric 144. Thus, first portion 192 may be described as formed on, over, above or touching tunnel dielectric 144, a top surface of tunnel dielectric 144, surface 125, channel 122, or active region 124. Tunnel dielectric 144 may be described as a tunnel oxide, or a gate dielectric. FIG. 1C also shows conformal dielectric layer 112 formed on electrode 190 and regions 132. Layer 112 may be an inter-poly dielectric. Conductive material layer 114 is formed on layer 112. Layer 114 may be a control gate or word line. Isolation regions 132 are shown formed adjacent to, touching, beside or between active regions 124, dielectric 144, and portion 192. Isolation regions 132 may be described as trench isolation or shallow trench isolation (STI).

Transistor 102 is shown in FIG. 1C having diffusion regions 176 and 178, such as junction regions or source/drain regions adjacent to and/or touching surface 125, channel 122 and/or active region 124. Accordingly, channel 122 may be a channel and/or have top surface 125 with four sides, such as two sides disposed towards, adjacent to, or touching regions 176 and 178; and two sides adjacent, disposed towards, or touching isolation regions 132. Thus, when properly biased, such as by applying a proper bias voltage to program or store a charge in electrode 190, a field may be set up under tunnel dielectric 144 to allow charged carriers to travel between region 176 and 178, such as to allow the cell to be read to identify existence of the charge. Diffusion regions 176 and 178 may be described as formed on or in active region 124. Similarly, electrode 190 and/or dielectric 144 may be described as formed on, over, or in substrate 120. Transistor 109 may be a transistor similar to the descriptions herein for transistor 102 (including as shown and described for FIG. 1C).

Transistors 102, 104, and 109 may be part of an array of flash memory device cells. Programming of the cells can be done by applying a proper electric field or “bias” across a tunnel dielectric 144, which causes electrons to be stored in a floating gate portion 194. Similarly, the cells can be erased by applying a proper electric field or “bias” (e.g., a field that has an opposite polarity as compared to the field for programming) across the tunnel dielectric 144, which causes electrons stored in a floating gate portion 194 to be removed, such as by causing them to tunnel through tunnel dielectric 144 and into active region 124.

Substrate 120 may be a polycrystalline or single crystal structure of one or more semiconductor materials, such as silicon, silicon germanium, and/or another semiconductor material. Substrate 120 may be formed from, deposited with, or grown using various suitable technologies for forming a semiconductor base or substrate, such as a silicon wafer. Substrate 120 may form by chemical vapor deposition (CVD), atomic layer deposition (ALD), blanket deposition, epitaxial deposition, or other similar forming processes. Substrate 120 may be a relaxed, non-relaxed, graded and/or non-graded semiconductor material. Substrate 120 may also be under a strain, such as a tensile or compressive strain. Descriptions above for substrate 120 also apply to active region 124 and channel 122.

In some embodiments, substrate 120 may be considered a semiconductor “bulk” layer, such as where isolation regions (e.g., regions 132) are required to electrically isolate transistor 102 from transistor 109 and/or other adjacent electronic devices on or in substrate 120. Alternatively, in some cases, substrate 102 may be a semiconductor on insulator (SOI) substrate, such as wherein insulator layer (not shown) may be disposed between substrate 102 and active region 124 (e.g., between substrate 120 and channel 122, and regions 176 and 178).

Isolation regions 132 are shown formed adjacent to, touching, beside or between active regions 124, and/or channels 122. Isolation regions 132 may be described as trench isolation or shallow trench isolation (STI). Regions 132 may be formed of one or more insulator materials such as dielectric material, oxide material, silicon dioxide, silicon oxy-nitride, tunnel oxide, semiconductor oxide material, or other insulator material formed on or in substrate 120. In some cases, forming isolation regions 132 may be include etching a trench in substrate 120 and filling the trench with insulator material. The trench may be filled using one or more plasma processes (e.g., high density plasma oxide), thermal processes (e.g., to form thermally grown oxide), and the like to grow or deposit the insulator material to a certain thickness in all of the trenches, at once. Thus, transistor 102, or components thereof, may be electrically isolated from adjacent transistors (e.g., transistor 109 and/or transistors further distal than region 132 from channel 122), but may or may not be electrically isolated from substrate 120.

Also, tunnel dielectric 144 may be an insulator such as described for isolation region 132, an insulator known for a tunnel dielectric, and the like. In some cases, dielectric 144 may be or include a thermally grown silicon dioxide (SiO₂), or other tunnel high quality dielectric type material.

The thickness or height of dielectric 144, portion 192, and/or portion 194 may each be generally consistent throughout and conform to the topography of surface 125.

Transistors 102 and 109 and components thereof may be further processed, such as in a semiconductor transistor fabrication process that involves one or more processing chambers to become part of “flash” memory, a NMOS transistor, a flash cell and the like. For example, a bit line (BL) or other interconnect or conductor may be formed to (e.g., to a top surface of) region 176, and/or region 178. Also, a word line (WL) or other conductor may be formed conformally over or above electrode 190 (e.g., separated from top surface 150 of second portion 194 by layer 112).

FIG. 1D also shows transistor 102 having electrode 190 with top surface 150, first portion 192 having width W2 and second portion 194 having width W1, where width W1 is less than width W2. First portion 192 also includes sidewalls 163 and 164, and top surfaces 160, 161, and 162. For example, top surface 160 may be a surface which second portion 194 is on or touching. Second portion 194 is shown having sidewalls 151 and 152, each intersecting the top surface of portion 192. For example, sidewall 151 may be described as intersecting top surface 160, 161, and 162 to form corner 167 (e.g., by intersection surface 160 and 161). Similarly, sidewall 152 may intersect top surface 160, 161, and 162 to form corner 168 (e.g., such as by sidewall 152 intersecting surface 160 and 162). It is also considered that sidewalls 151 and 152 may increase in width as they extend distally from surface 160 toward surface 150, such as to form a fluted or funnel like shape. In these embodiments, width W1 may be greater at surface 150 than it is at surface 160.

Surface 160, 161, and 163 may be described as disposed away from surface 125 and/or channel region 122. Also, sidewalls 163 and 164 may be described as perpendicular, angled away from, and/or not parallel with surface 125. Also, sidewalls 151 and 152 may be described as perpendicular to, angled away from, and/or not parallel with surface 160, 161, and/or 162. Surfaces 162 and 162 may be described as extending beyond sidewalls 151 and 152 respectively.

According to some descriptions, corner 167 and 168 may be described as “L” shaped and/or electrode 190 may be described as an inverted “T” shaped gate electrode. It can be appreciated that a “corner” may describe or be described by the intersection, joining, or coming together of two surfaces (surfaces which may or may not be planar) at a point or location. For instance, two substantially planar portions of two surfaces may join together to form a “sharp” corner, such as where the portions of the surfaces do not curve at or “near” the point or location of joining or intersection. Alternatively, the two portions of surfaces may curve towards each other such as to form a “curved corner” or transition between the portions of surfaces “near” or at the point or location of joining or intersection. Thus, a “curved corner” may have surfaces that begin curving towards each other at a distance greater than 2 or 3 nm from the location of an intersection of an extension of the surfaces. In some cases “near” may define a distance greater than 2 or 3 nm from the location of an intersection of an extension of the surfaces. For instance, FIG. 1D shows corner 168, such as a “sharp” corner, and corner 167, such as a “curved” corner. In some cases, corner 167 may have an arc radius less than or equal to the distance of width W1. As shown in FIG. 1D, corner 167 and/or 168 may form angle A such as a right angle, or 90° angle between portions of surfaces 151 and 161, and 152 and 162 respectively. In some cases, angle A may be 80, 85, 90, 95, 100 or any range between any number of combination thereof of degrees. For example, angle A may be between 85 and 95 degrees. In some cases, angle A may be approximately 90°. Corner 167, 168, or another corner described herein may be sharp corners, curved corners, and/or form angle A.

It can be appreciated that other corners, such as those shown as “sharp” corners in figures herein, may be more rounded or may be “curved coners”. For instance, corners of layers 412 and 112 may be more rounded, may be “curved coners”, or may be shaped appropriately for a layer of material formed by conformal deposition (e.g., a conformal layer).

FIGS. 1C and 1D also shows conformal dielectric layer 112 formed on top surfaces 150, 161, 162, and top surfaces 134 of isolation regions 132. Surfaces 134 of adjacent isolation regions 132 or of all isolation regions 132 may be parallel, the same height, or surfaces of a single plane. Layer 112 may also be formed on sidewalls 151, and 152. Similarly, layer 112 may be described as formed in, touching, or on corners 167 and 168. Layer 112 has width W4 at sidewalls 151 of transistor 109 and 152 of transistor 102.

Conductive material layer 114 is formed on, above, or touching layer 112. Layer 114 has width W3 between sidewalls 152 of transistor 102 and 151 of transistor 109. FIG. 1D also shows width W5 such a width between sidewall 164 of transistor 102 and sidewall 163 of transistor 109. In some cases, width W5 may correspond or be equal to the half-pitch of or between transistors 102 and 109.

According to embodiments, instead of being level or planar with surfaces 161 and 162, surface 134 may be level with the top or bottom surface of layer 144. As layer 112 may be a conformal layer of material, in these cases layer 112 may have corners formed as a result of the shape of corner 168, the corner between surface 162 and sidewall 164, and the corner between sidewall 164 and surface 134. Thus, here, layer 112 dips down towards width W5 to form another surface having a width less than width W3 above surface 134 and between transistor 102 and transistor 109. This other surface may have a width similar to width W4; and/or a width of approximately four, five, or six nanometers.

Portion 192 and/or portion 194 may be formed of semiconductor material, conductive material, such as silicon, single crystal silicon, polycrystal silicon, and the like. Portion P1 and P2 may be considered a P1 polysilicon material. In some cases, portion 192 and/or 194 may be more than one layer of different materials. Alternatively, in some cases, portion 192 and 194 may be the same material. Portion 192 and/or 194 may be formed by a process as described for layer 144. For instance, at surface 160, material of portion 194 may be on, or touching material of portion 192. In some embodiments, portion 194 may be a material densified by annealing to reduce voids, defects, or non-crystal bonds in the material. Also, portion 194 may have top surface 150 polished by a chemical mechanical polishing (CMP) process.

Layer 112 may be a layer of insulator material, dielectric material, material described for region 132, and ILD material, and/or other inter-poly dielectric (IPD) material. According to embodiments, layer 112 may include a polycrystalline or single crystal dielectric or insulator layer of one or more materials, such as silicon oxide, silicon nitride, and/or the like. Also, layer 112 may be described as an inter-poly dielectric layer, such as one or more layers of high k dielectric material. In some cases, layer 112 may represent three layers of material, such as a layer of silicon oxide on or touching a layer of silicon nitrate which is on or touching a different layer of silicon oxide. Each of these layers may be approximately five nanometers in thickness. Thus in this instance, width W4 would be approximately 15 nanometers.

Layer 114 may be a word line (e.g., a control gate (CG) polyword line), such as a layer of conductor or semiconductor material. Layer 114 may include poly-silicon, conductive material, and the like for forming a WL, CG, or control gate polyword line. In some cases layer 114 may be described as a P2 polysilicon material (e.g., while electrode 190 is a P1 polysilicon material). Where layer 114 is a conductive metal, gate electrode 190 may have smaller widths and heights. Thus, layer 114 may be used to simultaneously bias gate electrodes 190 of transistors 102 and 109 to activate transistor 102 and 109, such as to program or erase those transistors. For instance, it may be beneficial or desired to erase transistor 102 and 109 simultaneously where those transistors are flash cells of a flash memory, and/or other non-volatile memory. Also, the bit lines and be used to program or erase each of those transistors independently.

Electrode 190 may be described as a “floating” gate, such as a gate insulated from word line layer 114 by inter-poly-dielectric layer 112 and/or insulated from channel 122 (and from active region 124) by tunnel dielectric 144. Thus, gate electrode 190 may hold a charge for a long period of time. This charge may be maintained for five years, or until control gate layer 114 is erased, such as with a bias opposite that used to program it, thus, resetting or removing (e.g., to lower) a threshold voltage at which the cell turns on.

A benefit of the inverted “T” shape of gate electrode 190 is that transistor 102 and transistor 109 may be formed closer to each other, such as to reduce the half-pitch spacing between those transistors. For example, the smaller width W1 of second portion 194 as compared to first portion 192 may allow for flash cell scaling of the transistors beyond 50 nm half-pitch (e.g., a spacing or half-pitch of the transistors of less than 50 nm). This spacing reduction applied in both NOR and NAND based flash memory technologies. For instance, the smaller width W1 as compared to width W2 allows for a sufficient width W4 of layer 112 as well as a sufficient width W3 of layer 114 between transistors 102 and 109 such that W4 may be thick enough to: (1) reduce parasitic capacitive effects between adjacent flash cells or cell floating gates (e.g., reduced as compared to a square shaped gate electrode at the same half-pitch spacing, or maintain for an inverted “T” shape gate electrode at a reduced half-pitch spacing by allowing a sufficient thickness of layer 114 (e.g., layer 112 and 114) to extend between FGs); and/or (2) increase gate coupling ratio (GCR) for each of transistors 102 and 109; such as while maintaining or minimizing loss of performance.

Moreover, according to embodiments of the invention, surface 134 may be lower or high than that shown in FIG. 1D. For instance, surface 134 may be lowered or extend farther down into region 132 than as is shown in FIG. 1D to reduce parasitic capacitive effects between adjacent flash cells or cell floating gates (e.g., by allowing layer 114 (e.g., layer 112 and 114) to extend deeper between FGs) while maintaining or minimizing loss of performance. Lowering surface 134 may also increase gate coupling ratio (GCR) for each of transistors 102 and 109. In some cases, surface 134 may be lowered to be parallel with surface 125 or the lower surface of portion 192. For instance, surface 134 may be lowered so that the width or depth (e.g., below surface 150) of word line material (e.g., layer 114) between cells may be increased to reduce parasitic capacitive effects between adjacent flash cells, such as where the depth and thickness of word line material shields cross-talk (e.g., acts as a Faraday Cage or metal conductor shield) between adjacent FGs.

More particularly, a sufficient width W4 for layer 112 may be 15 nm, or a width able to withstand a voltage high enough to program and erase transistor 102, and able to provide low enough leakage. Likewise, a sufficient width for W3 may be at least 20 nm in width or a width to provide a sufficient conductivity of a voltage in layer 114 to program and erase transistor 102. Also, a sufficient width W2 for gate electrode 190 or portion 194 may be a width to provide good flash cell design (e.g., selection of widths W1, W2, W3, and/or W4) by being a cell active width which is wide so that a high cell read current is provided. Also, a factor in the size of width W2 may be the desire to provide good capacitive coupling between layer 114 and electrode 190. Thus, it is possible to shape the gate electrode so that the lower portion, portion 192 is wider, while the upper portion, portion 194 is not as wide as portion 192, allowing the transistors to be formed closer together, while still providing sufficient spacing of two times width W4 plus one times width W3 between portions 194 of those transistors having sufficient widths W1, W2, W3, and W4. This design (e.g., selection of widths W1, W2, W3, and/or W4) may maintain a sufficiently wide active region (e.g., width of surface 125 and/or channel 122) for transistor purposes that is also under the control of the floating gate. At the same time, this design may provide sufficient capacitive coupling between layer 114 and electrode 190 for transistor to performance.

Moreover, in some cases, due to the design of electrode 190 (e.g., due to width W1 being less than width W2, and/or formation of corners 167 and 168) it may not be necessary to increase GCR in other ways, such as by reducing the cell active width (e.g., the width of surface 125 and/or channel 122) below 30, 35, or 40 nm. As a result, a sufficient width W4 and width W3 may be accommodated without reducing active cell width, cell read current, or reducing performance of the cell or transistor. Similarly, this design may not require the use of a very high dielectric constant material for layer 112 that does not extend between electrodes 190 or portions 192 but provides sufficient capacitive coupling (e.g., for performance) but does increase leakage current between layer 114 and the gate electrode and may not be compatible with the flash process or meet data retention.

Also, in some cases portion 192 and portion 194 may both be formed of polysilicon. According to embodiments for example, width W1 may be a width of 10, 15, 20, 25, 30, a range between any number thereof or any combination of numbers thereof in nanometers (nm) in width. In some cases, width W1 may be in a range of between 15 and 25 nm. Also, width W1 may be approximately 15, 20, or 25 nm. The term “approximately” as used herein may indicate within 5% of the indicated value.

In some embodiments, width W2 may be a width for a gate electrode, gate dielectric or channel region of a transistor, flash memory transistor, NMOS transistor, and the like. Width W2 may be in a range between 30 and 40 nm. In some cases, width W2 may be approximately 30, 35, or 45 nm. It is also considered that width W2 may be equal to the half-pitch. Selecting width W2 equal to or approximately the half-pitch, and/or as indicated above, may provide a benefit of allowing for a wide active region under portion 192, such as where the active region or channel has a width less than or equal to width W2 (e.g., such as to provide a high cell read current).

Width W3 may be equal to the pitch minus width W1 minus two times width W4 (e.g., such as where the pitch is 80 nm, width W1 is 20 nm, and width W4 is 15 nm to provide width W3 of 30 nm). Width W3 may be referred to as the P2 (e.g., CG poly2 width) such as having a minimum width W3 of 15 nm for a poly-silicon gate and a minimum of 10 nm for a metal gate (e.g., such as having width W3 in a range between those minimums and a maximum of 45 nm).

Width W4 may be in a range of 12 to 18 nm. Also, width W4 may be approximately 12, 15, or 18 nm. For example, a benefit of selecting values for width W3 and/or width W4 (e.g., as noted above) may be providing good capacitive coupling (e.g., for performance) between layer 114 and gate electrode 190 (e.g., between the control gate and surfaces 150 and sidewalls 151 and 152).

Width W5 may be in a range of between 15 and 25 nanometers in width. For example, a benefit of selecting width W5 (e.g., as noted above) may be a cell or device pitch or a width resulting in a desired half-pitch, width W3, width W4, width W1, width W2 and/or relationship there between as described above.

Height H1 may be in a range of between 45 and 75 nanometers. In certain cases, height H1 may be approximately 45, 60, or 75 nanometers. Height H1 may be selected (e.g., as noted above) to provide a benefit of good capacitive coupling between layer 114 and portion 194 of gate electrode 190 (e.g., by providing sidewalls 151 and 152 with a sufficient height for good capacitive coupling which is sufficient for transistor performance). Likewise, width W1 may be selected to provide similar good capacitive coupling between portion 194 and layer 114.

Height H2 may be in a range of between 20 and 40 nanometers. Also, height H2 may be approximately 10, 20, or 30 nanometers. A benefit of selecting proper height H2 (e.g., as noted above) may be to provide a sufficient field in channel 122 for a high cell read current between region 176 and 178. Similarly, width W2 may be selected to provide a similar benefit, such as by being a width greater than a width of channel 122 and/or surface 125.

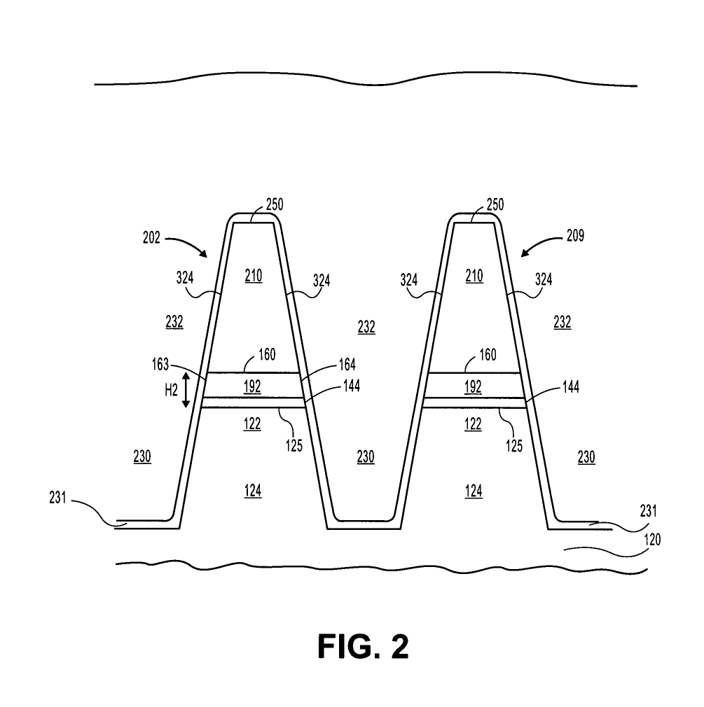

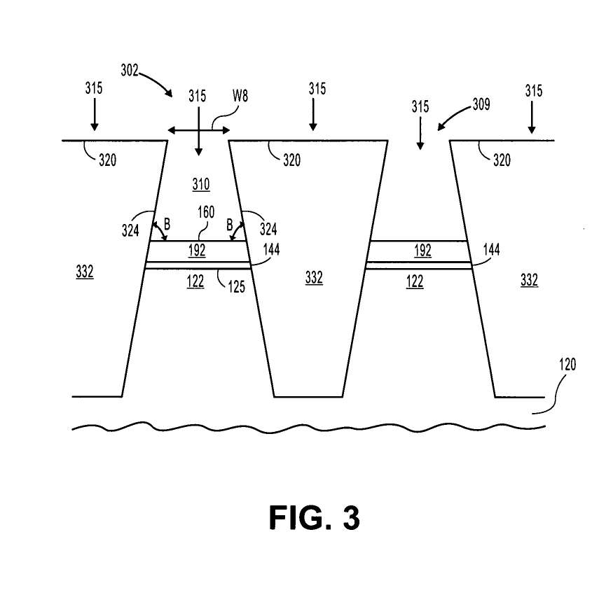

FIG. 2 is a schematic cross sectional view of a portion of a substrate having a dielectric layer on a first portion of the gate electrode over a channel region to define an active region, and isolation regions between the active regions. The cross sectional view of FIG. 2 may be the same as that of FIG. 1D and/or may show a substrate and “devices” prior to processing (e.g., see FIGS. 3-10) to form the substrate and transistor devices of FIG. 1D. Specifically, features 202 and 209 of FIG. 2 may become transistors 102 and 109. FIG. 2 shows dielectric portion or layer 210 on or touching first portion 192 which is on or touching tunnel dielectric 144 which is on or touching surface 125 of channel 122, all of which may be described as in or on active region 124 and/or substrate 120. FIG. 2 also shows isolation regions 232, such as formed of an insulator material and/or by a process as described for regions 132. Sidewalls 324 may describe sidewalls of insulator material, of a dielectric portion, of dielectric layer 210 and/or of regions 232. For example, sidewalls 324 may describe sidewalls of region 232 disposed on opposite sides of top surface 160 (e.g., such as inner sidewalls or sidewalls facing each other) and extending above top surface 160 at an inward angle towards each other. FIG. 2 also shows top surface 250 of dielectric portion 210, such as defining where sidewalls 324 end.

Thus, isolation regions 232 may define or electronically isolate the active region 124 of transistor structures to be formed from features 202 and 209. Specifically, regions 232 may become regions 132 to provide isolation of channel, diffusion regions, sources and drains, and/or gates as described above for regions 132 of FIG. 1D.

Dielectric layer 144 may be formed by silicon dioxide growth on bare silicon or semiconductor material (e.g., on or touching surface 125). For example, tunnel dielectric 144 may be formed by deposition, such as by chemical vapor deposition (CVD), atomic layer deposition (ALD), blanket deposition, and/or other appropriate growing, depositing, or forming processes. Also, following formation of layer 144, a “thin” portion or layer of semiconductor material may be formed as first portion 192. For instance, layer 192 may be formed by CVD, ALD, and/or other formation processes described herein to be on or touching layer 144. First position 192 may be considered to include or not to include layer 144. For example, FIGS. 1 and 2 show portion 192 having height H2 which includes the height or thickness of layer 144. In such a case, portion 192 may be described as on or touching surface 125. Alternatively, layer 144 may be considered a layer below layer 192, such as a layer between and touching surface 125 and a bottom surface of layer 192. Dielectric portion or layer 210 may be formed on or touching surface 160 of portion 192. Portion 210 may be formed by processes as described for forming portion 192. Dielectric layer 144, portion 192, and layer 210 may be formed prior to forming regions 232, such as where those layers and portions are formed as layers of material on substrate 120 including the area between features 202 and 209 (e.g., such as where surface 125 extends the entire width of FIG. 2).

STI patterning may be used to define diffusion regions (e.g., such as regions 176 and 178) and isolation regions (e.g., regions 132 are formed from regions 232). Regions 232 may be formed by etching through layer 210, portion 192 and layer 144 to define trenches 230 in which will be formed isolation regions 232 (e.g., regions 132). Next, the trench oxidation can be performed such as to form a thin oxide layer 231 from, in, or on trenches 230, for example, oxidation layer 231 may consume between one and five nanometers, such as by consuming approximately one, two or three nanometers of the surface of substrate 120, region 124, layer 144, portion 192, and/or layer 210.

Following formation of layer 231, an isolation oxide deposition, such as using high density plasma (HDP), can be performed to form regions 232, as shown in FIG. 2. This formation may include formation by CVD, ALD and/or pother processes as describe for forming layer 144. In some cases, material of region 232 may be described as a high density plasma oxide, and only be deposited by a high density plasma oxide deposition process to fill trenches 230 and form a layer of material having a height greater than top surface 250. After forming regions 232, the material of regions 232 may be etched or polished (e.g., such as by CMP) down to or below surface 250. A cross-section of the wafer at this point may be similar to that formed by a process used to form NAND transistors and/or a process to form self-aligned trench (SAT) devices or transistors (e.g., the edges of floating gate portion 192, such as sidewalls 163 and/or 164 are aligned with the edges of channel 122 (and optionally with the edges of layer 144) as shown in FIG. 1D) or self-aligned to the edges of trenches 230 (e.g., self-aligned to sidewalls 324).

Next, the dielectric layer 210 may be removed. Then, a thin layer of conformable insulator material may be formed over the wafer and anisotropically etched or removed from over and above surface 160, such as to expose surface 160.

FIG. 3 is a schematic cross sectional view of FIG. 2 after removal of a thickness of the isolation regions, and removal of the dielectric layer from on the first portion of the gate electrode. FIG. 3 shows features 302 and 309 such as features 202 and 209 after removal or polishing of a thickness of regions 230 and layer 210 to a height equal to or below the height of surface 250 (e.g., including removal of surface 250). Thus, surfaces 320 of isolation regions 332 may be formed by removing or polishing a thickness of regions 230 to expose surface 320 of the material of regions 232. Then, removal or etching of layer 210 may be performed to expose sidewalls 324 and surface 160. For example, after that removal or polishing of surface 250, etching as shown by arrows 315 may be performed, such as by selective etching selective to remove the material of layer 210 but leave the material of layer 332 to expose sidewalls 324 and surface 160. Such etching may be selective to the material of portion 192, such as to leave the material of portion 192, thus exposing surface 160, while removing the material of layer 210. Layer 210 may be removed by a wet etch, typically using a hot phosphoric chemistry, or by a dry etch sufficient to expose (e.g., to expose all of the surface of) sidewalls 324 and/or surface 160.

Hence, features 302 and 309 may be formed having top surface 160 of first portion 192 of what may be formed to become gate electrode 190. Also, features 302 and 309 may form sidewalls 324 of regions 332, where both sidewalls 324 are adjacent top surface 160. Thus adjacent sidewalls 324 may be described as disposed on opposite sides, inner sides, or facing each other with respect to top surface 160, and extending above top surface 160 at an inward angle B. Angle B may be an angle of between 85 and 89 degrees, or a range between any number thereof or combination of numbers thereof of degrees in angle. For example, angle B may be an angle of approximately 87 or 88 degrees.

In addition, removal of layer 210 may define shape 310 within, between, or defined by sidewalls 324 and surface 160 that may be described as a frustum, re-entrant, cone-shaped, tapered, inverted funnel, polyhedron, trapezoid with open top cross-sectional shape. In some cases, this shape may be described as the shape of opening 310 or the shape defined by sidewalls 324 and top surface 160.

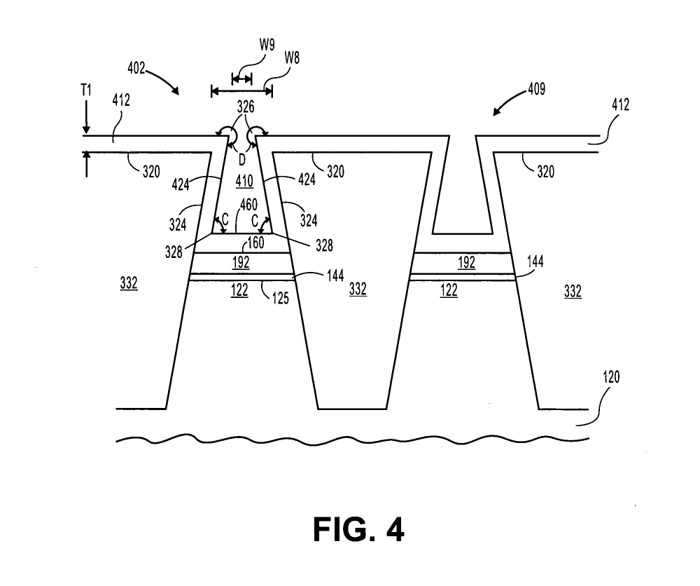

FIG. 4 is a schematic cross sectional view of FIG. 3 after forming a conformal layer of dielectric material on a top surface of the first portion of the gate electrode and on sidewalls of isolation regions adjacent the top surface. FIG. 4 shows features 402 and 409, such as features 302 and 309 after forming a conformal layer of insulator material or dielectric material on, over, and/or touching the structure of FIG. 3. Specifically, conformal layer 412 of insulator or dielectric material may be formed on, over, above, and/or touching surfaces 320, sidewalls 324, and surfaces 160, having thicknesses T1. Thus, layer 412 may be on or touching surface 160 of first portion 192, sidewall 324 of one or regions 332 and adjacent sidewall 324 of another of regions 332. Layer 412 may form top surface 406 above, parallel to, and/or over surface 160. Similarly, layer 412 may form sidewalls 424 beside, adjacent, parallel to, and/or on sidewalls 324. Also, layer 412 may have corners 328 forming angle C such as an angle described for angle B of FIG. 3. Similarly, layer 412 may have corners 326 forming an opening to opening or shape 410. Corners 326 may have angle D such as an angle that when added with angle C equals 360 degrees.

Surface 460 and sidewalls 424 may form an opening or shape 410 similar to that described for shape 310 formed by corresponding surfaces 160 and sidewall 324 of FIG. 3. Specifically, shape 410 may be substantially similar to shape 310 (e.g., have sidewalls 424 parallel to 324 and surface 460 parallel to 160 within 5 degrees). Layer 412 may be a layer of dielectric material, etch stop material, silicon dioxide material, silicon nitride material, “spacer” material (e.g., such as material used as a gate spacer), nitride, and/or another insulator material. Layer 412 may be the same material as the material of region 332, may be formed of more than one material, may be amorphous material, and/or may be a crystalline material. In some cases, layer 412 may be described as a thin oxide film for spacer formation. Layer 412 may be deposited by ALD, furnace, CVD, PECVD, PVD, sputter, process and/or the like. Layer 412 may be formed by a process as described for layer 144. Layer 412 may have a thickness of between 5 and 20 nanometers in thickness. For instance, layer 412 may have a thickness of approximately 10, 15 or 20 nanometers. In some cases, the thickness of layer 412 will vary between six and nine nanometers. It may be desired for the thickness of layer 412 to be approximately seven or eight nanometers, such as to form a sufficient thickness of spacer material T1 on sidewalls 324, to create a difference between W1 and W2 as described above. Similarly, thickness T1 may be desired to form a sufficient thickness of material 412 on surface 160 to be dry etched or selectively etched off of surface 160 to expose 160. Similarly, thickness T1 may be selected so that corners 326 are separated sufficiently for a dry etch or etch of layer 412 at surface 460 to expose surface 160. For example, width W8 and width W9 may be determined by T1 so that a sufficient amount of etchant material (e.g., such as dry etch material) can pass between corners 326 and into shape 410 to etch surface 460 to expose surface 160.

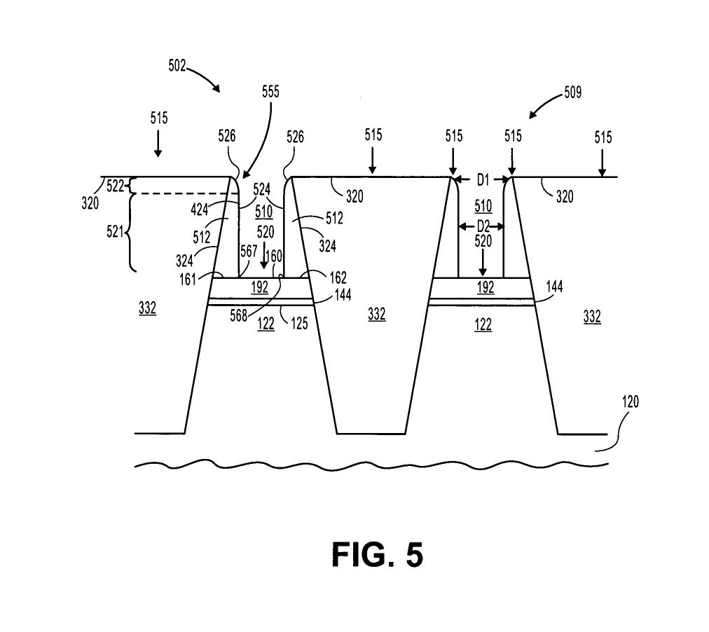

FIG. 5 is a schematic cross sectional view of FIG. 4 after removing the conformal layer of dielectric material from the top surface of the first portion of the gate electrode. FIG. 5 shows features 502 and 509, such as features 402 and 409 after etching a thickness of layer 412 from above layer 320 and layer 160 (e.g., removing surface 460 to expose surface 160). For example, arrows 520 may represent removing, polishing or etching, such as using an anisotropic etch (e.g., a wet etch, a dry etch, or another anisotropic etching process) to remove layer 412 from surfaces 320 and 160 (e.g., such as to expose or form an opening to surfaces 320 and 160). Removing the thickness of layer 412 may form corners 526 from corners 326; and corners 567 and 568 from corners 328. Specifically, as shown in FIG. 5, an anisotropic dry etch may be used to form fluted or funnel shape 555 from sidewalls 524 of spacers 512 left or remaining of layer 412. Shape 555 may include rectangular or flat surfaces 521 of sidewalls 524; and fluted, funnel-shaped, curving outward, or lipped surfaces 522 of sidewalls 524. In other words, removal of a thickness of layer 412 may form opening 510, such as an opening having fluted or funnel shape 555 with rectangular portion 521 and fluted portion 522 between spacers 512 and top surface 160. It may also be said that removing a thickness of conformal layer 412 may include anisotropically etching a thickness of that layer from sidewalls 424 to create first distance D1 between the conformal layer remaining on a top of sidewalls 324 that is greater in distance than distance D2 between the conformal layer below the top portion. For instance, distance D1 may be within portion 522. Also, distance D2 may not be within portion 522, may be within portion 521, may be at a bottom of shape 555 or at a mid-point of shape 555. In some cases, distance D2 may be less than width W2 as shown in FIG. 1. Otherwise, it may be said that removing layer 412 removes a thickness of that layer from or on sidewalls 324 to leave spacers 512 of dielectric material on sidewalls 324, where the spacers 512 define a fluted, funnel, rectangular, polyhedron, trapezoid with open top, or the like shape (e.g., but not a re-entrant, cone, or frustum shape).

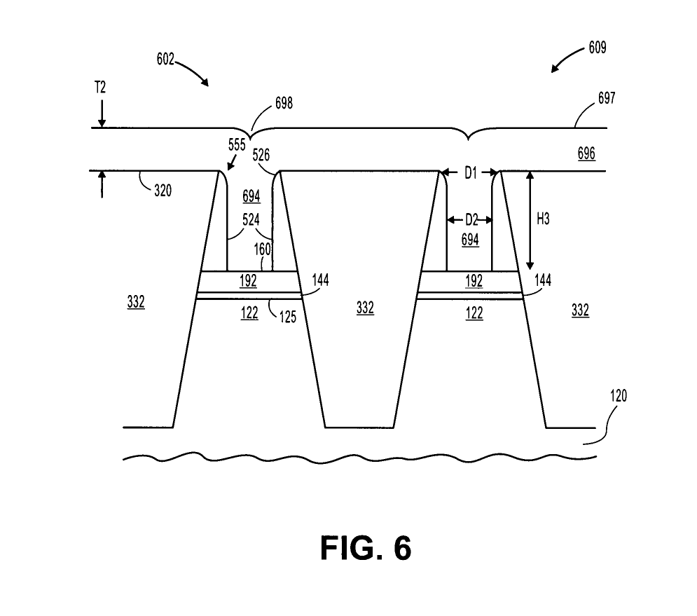

FIG. 6 is a schematic cross sectional view of FIG. 5 after forming a second portion of the gate electrode on the top surface of the first portion of the gate electrode. FIG. 6 shows layer 696 of semiconductor material formed on the structure of FIG. 5. For example, layer 696 is formed on and in features 502 and 509 to form features 602 and 609. Thus, layer 696 may include semiconductor material formed on surface 320, 160, and sidewalls 524. Layer 696 may also include semiconductor material formed in or on opening 510, corner 567, corner 568, corner 526, regions 521 and 522, spacers 512, first portion 192, and/or to surface 160. For instance, layer 696 may form shape 694 similar to the shape described above for opening 510 and/or a shape formed or defined by surface 160, sidewalls 524, corners 526, distance D1, distance D2, and/or corners 567 and 568. Shape 694 may be equal to or complementary to shape 555. Layer 696 may also have dimple 698 in top surface 697, such as a dip or dimple where surface 697 is recessed towards or into opening 510, shape 555, or shape 694.

Layer 696 may have thickness T2 such as a thickness greater than or equal to distance D1, distance D2 and/or thickens T1. For instance, thickness T2 may be selected to be a thickness greater than distance D1 or distance D2, such as to ensure filling space 510 or shape 555 with the material of layer 696. Layer 696 may be a material as described above with respect to forming substrate 120 or first portion 194. Layer 696 may be or include silicon, poly-silicon, single crystal silicon, silicon germanium, metal, conductor, semiconductor, and/or other materials for a gate electrode. Layer 696 or material of layer 696 may be described as on, above, over, or touching surface 160 and/or portion 192.

Layer 696 may be formed by a process as described above with respect to forming substrate 120, layer 412, layer 144 and/or first portion 194. In some cases, layer 696 may be formed by depositing, such as by CVD, ALD, or other processes noted herein, a layer of poly-silicon to form shape 694 which may eventually become portion 194 of the field gate. Shape 694 may be described as a fluted shape, funnel shape, or frustum shape.

Due to the aspect ratio (e.g., the height H3 of shape 694 as compared to the width which may be described as distance D1 or distance D2) voids (e.g., spaces having gas or nothing within the material of layer 696) may develop in the material of shape 694. The aspect ratio may be described as the width over the height, which may be described as distance D1 or distance D2 divided by height H3 in FIG. 6. Voids may form in the material of shape 694 when the aspect ratio becomes greater than one half or three quarters. Annealing, such as high temperature annealing, may be performed to remove, reduce, create fewer voids, to create material of layer 696 in shape 694 having fewer voids and being more pure, resulting in a increased conductivity, capacitance, and charge storage for shape 694 and/or portion 194.

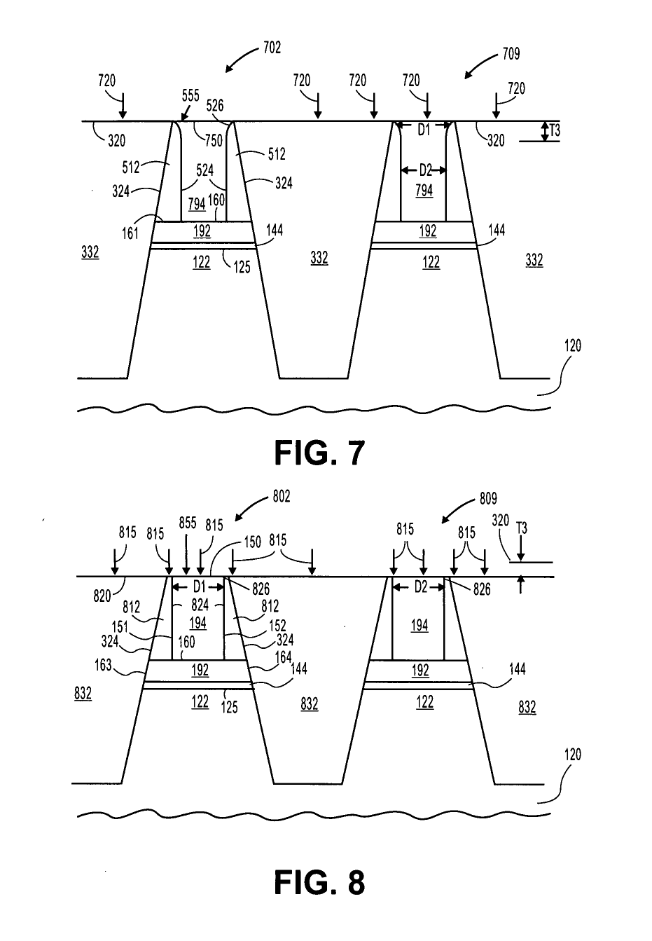

FIG. 7 is a schematic cross sectional view of FIG. 6 after removing a thickness of the second portion of the gate electrode. FIG. 7 shows the structure of FIG. 6 after removal, etching, or polishing of a thickness of layer 696, such as shown by arrows 720. The thickness of layer 696 of features 602 and 609 may be removed or polished to form features 702 and 709. The removal of a thickness of layer 696 may be performed before or after annealing of material of layer 696. For instance, a thickness greater than or equal to thickness T2 of layer 696 may be polished, such as by CMP of top surface 697. The polishing may stop at surface 320 of the isolation regions 332 or continue, by polishing a thickness of surface 320 of material of regions 332. For instance, FIG. 7 shows where removal or polishing stops at surface 320 and leaves shape 794 of layer 696 between sidewalls 524 and having top surface 750. Shape 794 may have a shape similar to the shape described for shape 694 and/or shape 555, such as having corners 526, sidewalls 524, and/or being on, touching, or having surface 160.

In some cases, after forming features 702 and 709 of FIG. 7, a thickness of regions 332 may be removed and then spacers 512 may be removed to form transistors 102 and 109 from features 702 and 709. However, in other cases, or an additional removal process (such as a process performed after the process forming features 702 and 709 is completed or finished and after a delay in time thereafter) may be performed to remove a thickness of regions 332 that includes corners 526 and/or the portion or region of shape 794 having distance D1.

For example, additional polishing may be performed to remove the flute of the fluted shape, curve of the funnel shape, and/or curved portion of the re-entrant shape, and/or curved portion of the frustum shape of shape 794. FIG. 8 is a schematic cross sectional view of FIG. 7 after removing an additional thickness of the second portion of the gate electrode and a thickness of the isolation regions. FIG. 8 shows features 802 and 809 after removal or polishing of features 702 and 709 in addition to that shown in FIG. 7, such as shown by arrows 820. For example, removal or polishing of thickness T3 of surfaces 320, and 750 may be performed to remove corners 526, and/or the portion of shape 794 having distance D1, to form second portion 194. Thus, the shape of portion 194 may define a rectangular, trapezoidal, and/or parallelogram shape.

Surface 750 of shape 794 may be removed or polished, along with surface 320, sufficiently to remove thickness T3 of shape 794 between spacers 512 on sidewalls 524. It is also worth noting that thickness T3 of spacers 512 has been removed forming spacers 512 to form spacers 812 and from regions 332 to form regions 832. Sidewalls 151 and 152 of portion 194 may correspond to material of portion 194 touching sidewalls 824 of spacers 812.

Also, the annealing noted above to remove voids in portion 194 may be performed before or after the removal to form features 802 and 809. This annealing may be done prior to removing thickness T2 and/or T1 to avoid or decrease a risk of void/seam exposure in surface 750 or 150 after removal or CMP.

Specifically, FIG. 8 shows sidewalls 824 having non-curved or sharp corners at top 826 of portion 194. Similarly, portion 194 has distance D2 or width W1 at top portion 826. Portion 194 also has top surface 150 forming corners with sidewalls 151 and 152. Isolation regions 832 have top surface 820, such as a remaining surface after thickness T3 of regions 332 is removed from surface 320. Thickness T3 may be a thickness of 1, 2, 4, 8, 10, a range between any number or combination thereof of distances in nm. For example, thickness T2 may be between five and six nanometers, between three and ten nanometers, or between four and eight nanometers. Also, thickness T3 may be approximately 3, 4, 5, 6, 8 or 10 nanometers. The polishing to remove thickness T3 (e.g., going from FIG. 6 to 7) may be done during or at the end of the polishing process to remove a thickness to surface 320 and 750 (e.g., going from FIG. 7 to 8), such as with a slurry change and the end to facilitate the overpolish and remove thickness T3 (e.g., some of the floating gate material). Of course, these polishings could also be done during separate processes.

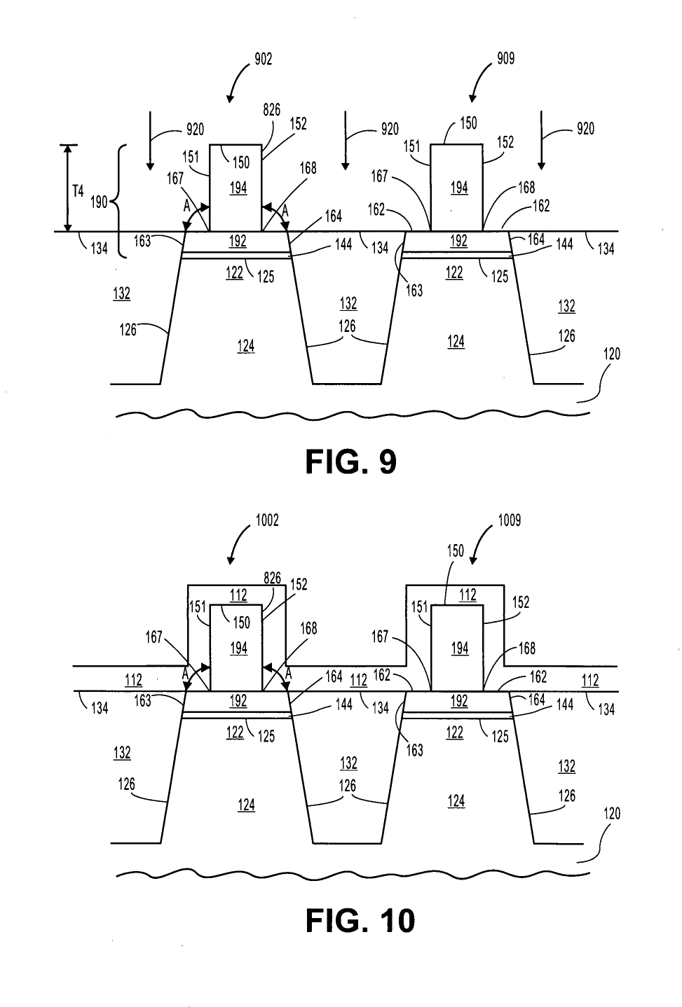

FIG. 9 is a schematic cross sectional view of FIG. 8 after removing a thickness of the isolation regions and removing the spacers of the conformal dielectric layer to expose the sidewalls of the first and second portions of the gate electrode. FIG. 9 shows features 902 and 909 formed after removing a thickness of regions 832 of features 802 and 809, such as shown by arrows 920. Specifically, thickness T4 may be removed, such as by etching, selective etching, or other processes for removing isolation region material. In some cases, one or more etch processes may be used to remove a thickness of regions 832 and to remove spacers 812. One or more etch processes may be used to remove at least thickness T4 of material 832 to form material 132. These same one or more processes may also remove spacers 812. Thus, sidewalls 324 of regions 832, or a thickness thereof, as well as surfaces 324 of spacers 812 are removed to expose outer surfaces 151 and 152 of portion 194 (the outer surfaces 324 being the material of conformal layer 412 adjacent to sidewalls 151 and 152). Similarly, removal of thickness T4 may stop at surfaces 161 and 162, but not expose sidewalls 163 and 164 of first portion 192. The etching of material 832 and spacers 812 may be described as etching of isolation oxide material and may include removing a thickness or not removing a portion of the total thickness of surface 150, side surfaces 151 and 152, and/or surfaces 161 and/or 162.

As noted, layer 412 (spacers 812) may be the same material as the material of region 332 (region 832). Thus, removal of spacers 812 may be done in the same or a separate removal or etch operation as the removal of thickness T4, such as in a selective etch to selectively etch material of regions 832 and spacers 812, but not to remove material of portion 194, or portion 192 (e.g., using a chemical etchant selective to the material of regions 832 and spacers 812 for a selected time or timed etch to stop approximately level with surfaces 161 and 162).

Alternatively, the etch process may be selective to remove regions 832 but leave spacers 812. That etch process may be supplemented by an additional etch (e.g., such as an etch performed after a delay after the etch) to remove the material of spacers 812. The removal or etch of material of spacers 812 may be selective with respect to portion 192, portion 194, and material of regions 132, such as to leave those materials, but remove material of spacers 812. After removal of spacers 812, gate electrode 190 having first portion 192 and second portion 194 are formed, such as shown in FIG. 9 and FIG. 1. Specifically, removing spacers 812 may include exposing sidewalls 151 and 152, top surfaces 161 and 162, and corners 167 and 168 of portions 194 and 192. It may be also said that the removal of spacers 812 exposes top surface 150, such as where a thickness of portion 194 is removed during the etching or removal of the spacers. Also, removal of spacers 812 may form corners 161 and 162 between sidewalls 151 and 152 and top surfaces 161 and 162.

Additional components of transistors 102 and 109 may be added to features 902 and 909 of FIG. 9 to form those transistors. FIG. 10 is a schematic cross sectional view of FIG. 9 after forming a conformal dielectric layer over the expose the sidewalls of the first and second portions of the gate electrode. Specifically, conformal insulator material layer 112 may be deposited over features 902 and 909, as shown to form features 1002 and 1009. Features 1002 and 1009 may be processed to become transistors 102 and 109, such as by forming or depositing semiconductor layer 114 over layer 112 to form transistors 102 and 109.

The foregoing description is intended to be illustrative and not limiting. Variations will occur to those of skill in the art. Those variations are intended to be included in the various embodiments of the invention, which are limited only by the spirit and scope of the appended claims.

What is claimed is:

1. A flash memory comprising:
a gate electrode having a first layer over a channel region and a second layer over the first layer, wherein the first layer comprises a surface disposed away from the channel region and the second layer comprises a first sidewall intersecting and forming a first corner with the surface, and a second sidewall intersecting and forming a second corner with the surface.

2. The flash memory of claim 1, wherein the first layer has a first width at the surface, the second layer has a second width over the surface, the first width is greater than the second width, the first layer is touching the surface, the surface extends beyond the first sidewall, and the surface extends beyond the second sidewall.

3. The flash memory of claim 1, wherein the first layer has a first width at the surface, the second layer has a second width over the surface, the first width is greater than the second width, the first sidewall is perpendicular to the surface, the second sidewall is perpendicular to the surface, and the first layer and the second layer comprise the same material.

4. The flash memory of claim 1, wherein the first layer is over a surface of the channel region having four sides, and further comprising a tunnel dielectric between the gate electrode and the surface of the channel region, a first diffusion region adjacent a first side of the channel region, a second diffusion region adjacent a second side of the channel region, a first isolation region adjacent a third side of the channel region, and a second isolation region adjacent a fourth side of the channel region.

5. An apparatus comprising:
a gate electrode having a first portion over an active region of an electronic device and a second portion on a first surface of the first portion, wherein the first portion has a first width at the first surface, the second portion has a second width at a second surface of the second portion proximate to the first surface, and two sidewalls of the second portion form two corners with the first surface.

6. The apparatus of claim 5, wherein the first portion has a first height, the second portion has a second height, and the first height is less than the second height.

7. The apparatus of claim 5, wherein the first portion is formed on a tunnel dielectric, and is formed between two isolation regions.

8. The apparatus of claim 7, wherein the first portion comprises two sidewalls of the first portion, the second portion comprises a top surface, each isolation region comprises a top surface level with the first surface of the fist portion, and further comprising:
a conformal dielectric layer formed on the top surface of the second portion, the sidewalls of the second portion, two extensions of the first surface of the first portion, and the top surfaces of the isolation regions.

9. The apparatus of claim 8, wherein the gate electrode and the adjacent gate electrode are floating gates, the conformal dielectric layer is an inter poly dielectric layer, and a conductive material layer control gate poly word line formed on the conformal dielectric layer to simultaneously bias the gate electrode and the adjacent gate electrode.

10. The apparatus of claim 5, wherein the second portion comprises a material densified by annealing to reduce voids in the material, and has a polished top surface polished by a chemical mechanical polishing (CMP) process.

11. The apparatus of claim 5, wherein the two sidewalls of the second portion increase in width as they extend distally away from the first surface towards a top surface of the second portion to form a fluted shape.

12. A method comprising:
forming a conformal layer of dielectric material on a top surface of a first portion of a gate electrode on an active region of an electronic device, and on a first sidewall of a first isolation region adjacent the top surface, and on a second sidewall of a second isolation region adjacent the top surface, wherein the first sidewall and the second sidewall are disposed on opposite sides of the top surface and extend above the top surface at an inward angle towards each other, and the conformal layer defines a frustum shape;
removing the conformal layer of dielectric material from the top surface of the first portion of the gate electrode;
forming a second portion of the gate electrode on the top surface of the first portion.

13. The method of claim 12, wherein removing the conformal layer of dielectric material comprises anisotropically etching a thickness of the conformal layer on the first and second sidewalls to create a first distance between the conformal layer on a top of the first and second sidewalls that is greater than a second distance between the conformal layer below the top of the first and second sidewalls.

14. The method of claim 13, further comprising chemical mechanical polishing (CMP) a top surface of the second portion of the gate electrode and the top surface of the first and second isolation regions to remove a thickness of the second portion of the gate electrode between the conformal layer on a top of the first and second sidewalls.

15. The method of claim 12, wherein the conformal layer is thinner than a thickness of the first portion, the gate electrode is on a channel of semiconductor material of a flash memory, forming the conformal layer comprises forming the conformal layer on a top surface of the first and second isolation regions, and removing the conformal layer comprises removing the conformal layer from the top surface of the first and second isolation regions.

16. The method of claim 15, wherein removing the conformal layer comprises removing a thickness of the conformal layer on the first and second sidewalls to leave spacers of the dielectric material on the sidewalls of the isolation regions defining a fluted shape.

17. The method of claim 16, wherein forming a second portion of the gate electrode comprises forming the second portion having the fluted shape, and further comprising:
removing a sufficient thickness of the second portion of the gate electrode and the top surface of the first and second isolation regions to remove a flute part of the fluted shape of the second portion of the gate electrode.

18. The method of claim 17, wherein removing comprises chemical mechanical polishing (CMP) a top surface of the second portion of the gate electrode and the top surface of the isolation regions.

19. The method of claim 17, further comprising:
removing the first and second sidewalls of the two isolation regions to expose outer surfaces of the spacers; and
removing the spacers to expose a pair of sidewalls of the second portion of the gate electrode, to expose a pair of top surfaces of the first portion of the gate electrode, and to form a pair of corners between the sidewalls of the second portion of the gate electrode and the top surfaces of the first portion of the gate electrode.

20. The method of claim 12, wherein forming the second portion of the gate electrode comprises forming voids in the second portion of the gate electrode due to an aspect ratio of the second opening, and further comprising:
high temperature annealing the second portion of the gate electrode to reduce the voids.
